(19) United States
(12) Patent Application Publication
(10) Pub. No.: US 2025/0038049 A1
(43) Pub. Date: Jan. 30, 2025

(54) INTERCONNECT STRUCTURE AND FABRICATION METHOD THEREOF

(71) Applicant: Taiwan Semiconductor Manufacturing Company, Ltd., Hsin-Chu (TW)

(72) Inventors: Yen Yu Chen, Pingtung City (TW); Chung-Liang Cheng, Changhua County (TW); Ying-Han Chiou, Tainan City (TW)

(21) Appl. No.: 18/358,525

(22) Filed: Jul. 25, 2023

(51) Int. Cl. H01L 21/768; H01L 23/522

(52) U.S. Cl. CPC H01L 21/76844; H01L 21/76846; H01L 21/7685; H01L 21/76876; H01L 23/5226; H01L 21/76807; H01L 23/53223; H01L 23/53238

(57) ABSTRACT

A method of forming a semiconductor structure includes forming a conductive capping layer over a conductive feature, forming a dielectric layer over the conductive capping layer, forming an opening in the dielectric layer to expose a top surface of the conductive capping layer, forming an inhibitor film at the top surface of the conductive capping layer, depositing a barrier layer on sidewalls of the opening, removing the inhibitor film to expose the top surface of the conductive capping layer, depositing a supplementary liner on the barrier layer and the top surface of the conductive capping layer, and depositing a conductive material on the supplementary liner and filling the opening.

### BACKGROUND

The integrated circuit (IC) industry has experienced exponential growth. Technological advances in IC materials and design have produced generations of ICs, where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs.

Such scaling down has also increased the complexity of processing and manufacturing ICs and, for these advances to be realized, similar developments in IC processing and manufacturing are needed. For example, as multilayer interconnect (MLI) features become more compact with ever-shrinking IC feature size, interconnects of the MLI features are exhibiting increased contact resistance, which presents performance, yield, and cost challenges. It has been observed that higher contact resistances exhibited by interconnects in advanced IC technology nodes can significantly delay (and, in some situations, prevent) signals from being routed efficiently to and from IC devices, such as transistors, negating any improvements in performance of such IC devices in the advanced technology nodes. Accordingly, although existing interconnects have been generally adequate for their intended purposes, they have not been entirely satisfactory in all respects.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a cross-sectional view of layers involved in an interconnect structure of a semiconductor device, in accordance with some embodiments of the present disclosure.

FIGS. 2, 3, 4, 5, 6, 7, 8, 9, 10, 11, 12, 13, and 14 illustrate cross-sectional views of an interconnect structure at intermediate stages in the formation of a metal line and a via, in accordance with some embodiments of the present disclosure.

FIG. 15 shows a process flow for forming a metal line and a via in an interconnect structure, in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower.” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Still further, when a number or a range of numbers is described with “about,” “approximate,” and the like, the term is intended to encompass numbers that are within +/−10% of the number described, unless otherwise specified. For example, the term “about 5 nm” encompasses the dimension range from 4.5 nm to 5.5 nm.

IC manufacturing process flow is typically divided into three categories: front-end-of-line (FEOL), middle-end-of-line (MEOL), and back-end-of-line (BEOL). FEOL generally encompasses processes related to fabricating IC devices, such as transistors. For example, FEOL processes can include forming isolation features, gate structures, and source and drain features (generally referred to as source/drain features). MEOL generally encompasses processes related to fabricating contacts to conductive features (or conductive regions) of the IC devices, such as contacts to the gate structures and/or the source/drain features. BEOL generally encompasses processes related to fabricating a multilayer interconnect (MLI) feature that interconnects IC features fabricated by FEOL and MEOL (referred to herein as FEOL and MEOL features or structures, respectively), thereby enabling operation of the IC devices.

As IC technologies progress towards smaller technology nodes, MEOL and BEOL processes are experiencing significant challenges. For example, advanced IC technology nodes require more compact MLI features, which requires significantly reducing critical dimensions of interconnects of the MLI features (for example, widths and/or heights of vias and/or conductive lines of the interconnects). The reduced critical dimensions have led to significant increases in interconnect resistance, which can degrade IC device performance (for example, by increasing resistance-capacitance (RC) delay).

The present disclosure discloses embodiments of interconnect structures that provide low-resistance vias and metal lines structures (collectively, contact structures). Contact structures often include diffusion barrier layers. The diffusion barrier layer has the function of preventing the diffusion of the metal elements (such as copper) in the contact structures from diffusing into dielectric layers surrounding the contact structures. The diffusion barrier layer generally has a high resistivity, which increases contact resistance between the contact structures and the underlying interconnect features. In some embodiments of the present disclosure, the low-resistance contact structures include barrier layers selectively formed on sidewalls of the contact structures, but not formed on the underlying interconnect features. By not having the barrier layers directly contacting the underlying interconnect features, contact resistance and thus the overall resistance of the contact structures can be reduced.

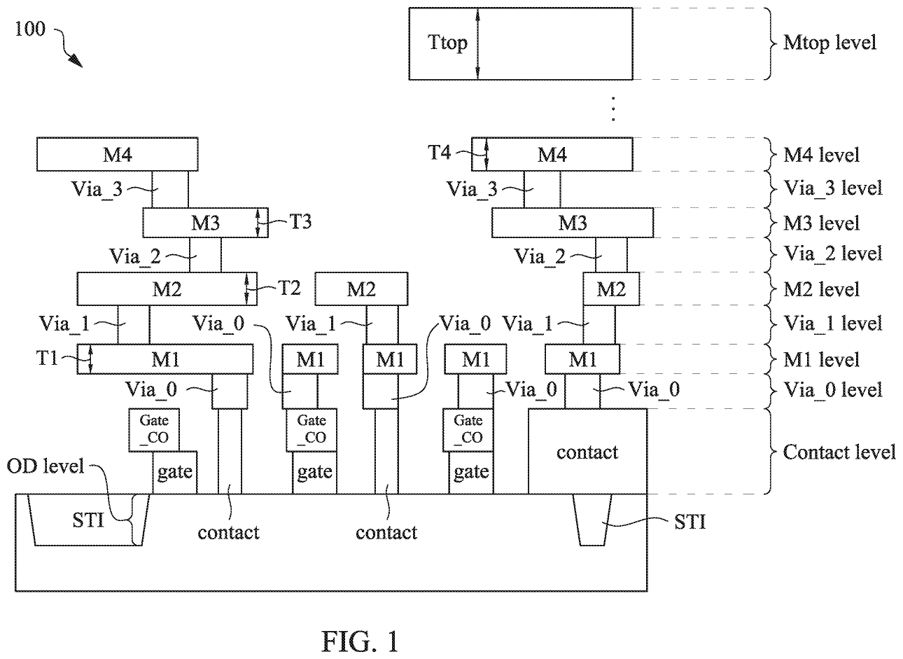

FIG. 1 illustrates a schematic cross-sectional view of a plurality of layers involved in a semiconductor device 100. It is noted that FIG. 1 is schematically illustrated to show various levels of interconnect structure and circuit device regions (e.g., transistors), and may not reflect the actual cross-sectional view of a semiconductor device 100. The interconnect structure includes a contact level, an OD (wherein the term “OD” represents “active region”) level, via levels Via_0 level, Via_1 level, Via_2 level, and Via_3 level, and metal-layer levels M1 level, M2 level, M3 level, M4 level . . . Mtop level. Each of the illustrated levels includes one or more dielectric layers and the conductive features formed therein. The conductive features that are at the same level may have top surfaces substantially level to each other, bottom surfaces substantially level to each other, and may be formed simultaneously. The contact level may include gate contacts (also referred to as contact plugs) for connecting gate electrodes of transistors to an overlying level such as the Via_0 level, and source/drain contacts (marked as “contact”) for connecting the source/drain regions of transistors to the overlying level. Thickness of the metal lines at the metal-layer levels M1 level, M2 level, M3 level, M4 level . . . Mtop level are denoted as T1, T2, T3, T4 . . . . Ttop, respectively. It is also noted that metal-lines at a higher level generally have a larger thickness than metal lines at a lower level (i.e., T1<T2<T3<T4< . . . <Ttop). Further, metal lines at a higher level generally have a larger pitch (e.g., center-to-center distance or edge-to-edge distance between adjacent metal lines) than metal lines at a lower level.

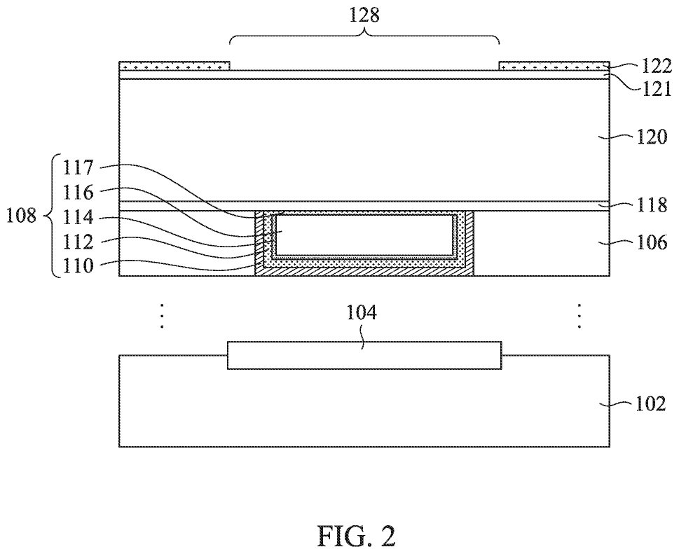

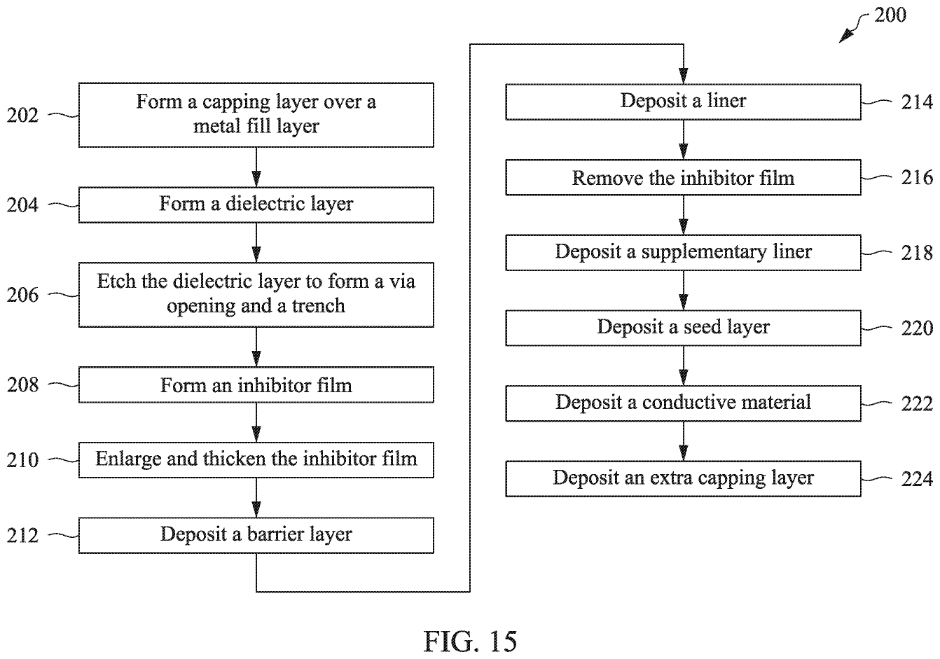

FIGS. 2 through 14 illustrate the cross-sectional views of intermediate stages in the formation of contact structures in the semiconductor device 100 in accordance with some embodiments of the present disclosure. Particularly, for the sake of simplicity, FIGS. 2 through 14 illustrate the cross-sectional views of intermediate stages in the formation of two consecutive metal-layer levels and the corresponding via level therebetween (e.g., a Mₓ level, a Via_x level, and a Mₓ₊₁ level, x representing an integer) of the interconnect structure of the semiconductor device 100 in accordance with some embodiments. Corresponding processes are also reflected schematically in the process flow 200 as shown in FIG. 15. Additional processes can be provided before, during, and after the process flow 200, and some of the processes described can be moved, replaced, or eliminated for additional embodiments of the process flow 200. Additional features can be added in the interconnect structure depicted in FIGS. 2-14, and some of the features described below can be replaced, modified, or eliminated in other embodiments of the interconnect structure depicted in FIGS. 2-14.

FIG. 2 illustrates a cross-sectional view of the semiconductor device 100. In accordance with some embodiments of the present disclosure, the semiconductor device 100 is a device wafer including active devices such as transistors and/or diodes, and possibly passive devices such as capacitors, inductors, resistors, or the like. In accordance with alternative embodiments of the present disclosure, the semiconductor device 100 is an interposer wafer, which may or may not include active devices and/or passive devices. In accordance with yet alternative embodiments of the present disclosure, semiconductor device 100 is a package substrate strip, which may include package substrates with cores therein or core-less package substrates. In subsequent discussion, a device wafer is used as an example of the semiconductor device 100. The teaching of the present disclosure may also be applied to interposer wafers, package substrates, packages, etc.

In accordance with some embodiments of the present disclosure, the semiconductor device 100 includes a semiconductor substrate 102 and the features formed at a top surface of the semiconductor substrate 102. The semiconductor substrate 102 may comprise crystalline silicon, crystalline germanium, silicon germanium, a III-V compound semiconductor such as GaAsP, AlInAs, AlGaAs, GaInAs, GaInP, GaInAsP, or the like. The semiconductor substrate 102 may also be a bulk silicon substrate or a Silicon-On-Insulator (SOI) substrate. Shallow Trench Isolation (STI) regions (not shown in FIG. 2, but shown in FIG. 1) may be formed in the semiconductor substrate 102 to isolate the active regions in the semiconductor substrate 102. Although not shown, through-vias may be formed to extend into the semiconductor substrate 102, wherein the through-vias are used to electrically inter-couple the features on opposite sides of the semiconductor device 100.

In accordance with some embodiments of the present disclosure, circuit devices 104 are formed on the top surface of the semiconductor substrate 102. Examples of the circuit devices 104 include Complementary Metal-Oxide Semiconductor (CMOS) transistors, resistors, capacitors, diodes, or the like. The details of circuit devices 104 are not illustrated herein.

Further illustrated in FIG. 2 is a dielectric layer 106. The dielectric layer 106 may be an Inter-Layer Dielectric (ILD) layer or an Inter-Metal Dielectric (IMD) layer. In accordance with some embodiments of the present disclosure, the dielectric layer 106 is an ILD layer, in which contact plugs are formed. The corresponding dielectric layer 106 may be formed of Phospho Silicate Glass (PSG), Boro Silicate Glass (BSG), Boron-Doped Phospho Silicate Glass (BPSG), Fluorine-Doped Silicate Glass (FSG), a silicon oxide layer (formed using Tetra Ethyl Ortho Silicate (TEOS)), or the like. Dielectric layer 106 may be formed using spin-on coating, Atomic Layer deposition (ALD), Flowable Chemical Vapor Deposition (FCVD), Chemical Vapor Deposition (CVD), Plasma-Enhanced Chemical Vapor Deposition (PECVD), Low-Pressure Chemical Vapor Deposition (LPCVD), or the like. In accordance with some embodiments of the present disclosure, the dielectric layer 106 is an IMD layer, in which metal lines and/or vias are formed. The corresponding dielectric layer 106 may be formed of a carbon-containing low-k dielectric material, Hydrogen SilsesQuioxane (HSQ), MethylSilsesQuioxane (MSQ), or the like. In accordance with some embodiments of the present disclosure, the formation of the dielectric layer 106 includes depositing a porogen-containing dielectric material, and then performing a curing process to drive out the porogen, and hence the remaining dielectric layer 106 is porous.

A conductive feature 108 is formed in the dielectric layer 106. Conductive feature 108 may be a metal line, a conductive via, a contact plug, or the like. In accordance with some embodiments, conductive feature 108 includes a barrier layer 110, a liner 112, a seed layer 114, a metal fill layer 116 over the seed layer 114, and a capping layer 117 over the metal fill layer 116. The barrier layer 110 may be formed of a conductive material such as Ta, TaN, TaC, Ti, TiN, TiC, and other suitable material that can block metal element diffusion, and may be deposited using ALD, CVD, ELD, or PVD and may be formed to a thickness between about 0.5 nm and about 5 nm. The barrier layer 110 may also be referred to as a diffusion barrier layer. In accordance with some embodiments of the present disclosure, the formation of the conductive feature 108 may also adopt the methods as discussed subsequently, so that the bottom portion of barrier layer 110 is not formed.

The liner 112 is deposited on the barrier layer 110. In some implementations, the liner 112 may be deposited using ALD, CVD. ELD, or PVD and may be formed to a thickness between about 0.5 nm and 3 nm. The liner 112 may be formed of suitable metal, metal nitride, or metal carbide, such as Co, CON and RuN. In one example, the liner 112 is made of Co. The liner 112 functions to increase adhesion between the seed layer 114 and the barrier layer 110. The liner 112 may also be referred to as an adhesive layer.

The seed layer 114 is formed on the liner 112. In some implementations, the seed layer 114 is a metal alloy layer containing at least a main metal element, e.g., copper (Cu), and an additive metal element, e.g., manganese (Mn). In one example, the seed layer 114 is a copper-manganese (CuMn) layer. In other embodiments, Ti, Al, Nb, Cr. V. Y. Tc, Re, or the like can be utilized as an alternative additive metal for forming the seed layer 114. The concentration (atomic percentage) of the additive metal element in the copper-alloy layer may range from about 0.5% to about 5%, in some embodiments. As explained in further detail below, the concentration of the additive metal element may vary in contact structures at different levels in some embodiments. In one example, the copper-alloy layer is a CuMn layer, and the contact structures at a higher level have a higher concentration of manganese than contact structures at a lower level. The seed layer 114 may be deposited by using ALD, CVD, ELD, PVD, or other suitable deposition techniques.

The metal fill layer 116 may be formed of copper, a copper alloy, aluminum, or the like. The barrier layer 110 has the function of preventing the diffusion of the material (such as copper) in the metal fill layer 116 into the dielectric layer 106. In some embodiments, the metal fill layer 116 may be deposited using PVD. CVD, ALD, electroplating, ELD, or other suitable deposition process, or combinations thereof. After the deposition of the metal fill layer 116, a planarization process such as a Chemical Mechanical Planarization (CMP) process or a mechanical polish process may be performed to remove excess portions of conductive material of the metal fill layer 116.

The capping layer 117 is deposited on the metal fill layer 116. The respective process is illustrated as process 202 in the process flow 200 as shown in FIG. 15. In some embodiments, the CMP process performed prior in removing excess portions of the conductive material of the metal fill layer 116 also slightly recesses the top surfaces of the metal fill layer 116 and the seed layer 114. The capping layer 117 is deposited on the recessed top surfaces of the metal fill layer 116 and the seed layer 114. The liner 112 may surround the capping layer 117 and separate the capping layer 117 from contacting the barrier layer 110. In furtherance of some embodiments, the top surfaces of the barrier layer 110, the liner 112, and the capping layer 117 may be substantially coplanar. In some other embodiments, the CMP process also recesses the liner 112, such that the capping layer 117 covers the top surfaces of the liner 112, the seed layer 114, and the metal fill layer 116. Thus, the capping layer 117 may physically contacts the barrier layer 110.

The capping layer 117 is formed of a conductive material, which may include, and is not limited to, metal, metal nitride, or metal carbide. In some implementations, the capping layer 117 may be formed of Co, CON, RuN, or a combination thereof. In furtherance of some embodiments, the capping layer 117 and the liner 112 have the same material composition. For example, both the capping layer 117 and the liner 112 may be formed of Co. As explained in further detail below, a supplementary liner that may have substantially the same material composition with the liner 112 will be deposited on the capping layer 117 at a bottom of a via opening. Having the capping layer 117 also made of the same material composition allows the conductive materials from the capping layer 117 and the to-be-formed supplementary liner merge into a thicker conductive layer, which helps further reducing contact resistance. In some other embodiments, the capping layer 117 and the liner 112 may include different material compositions. For example, the liner 112 may be formed of Co, and the capping layer 117 may be formed of CON. In the depicted embodiment, the capping layer 117 is thinner than the liner 112. Alternatively, the capping layer 117 may have the same thickness or thicker than the liner 112.

As also shown in FIG. 2, an etch stop layer 118 is formed over the dielectric layer 106 and the conductive feature 108. The etch stop layer 118 is formed of a material that has a high etching selectivity with relative to the overlying dielectric layer 120, and hence the etch stop layer 118 may be used to stop the etching of the dielectric layer 120. In accordance with some embodiments of the present disclosure, the etch stop layer 118 is formed of a dielectric material, which may include, and is not limited to, aluminum oxide, aluminum nitride, silicon nitride, silicon carbide, silicon oxynitride, silicon carbo-nitride, or the like. In various embodiments, the etch stop layer 118 may have a larger thickness than the liner 112.

A dielectric layer 120 is formed over the etch stop layer 118. The respective process is illustrated as process 204 in the process flow 200 shown in FIG. 15. In accordance with some embodiments, the dielectric layer 120 is an IMD layer or an ILD layer. The dielectric layer 120 may comprise a dielectric material such as an oxide, a nitride, a carbon-containing dielectric material, or the like. For example, the dielectric layer 120 may be formed of PSG, BSG, BPSG, FSG, TEOS oxide, HSQ, MSQ, or the like. The dielectric layer 120 may also be a low-k dielectric layer having a low dielectric constant value lower than about 3.5 or lower than about 3.0.

A capping layer 121 is formed over the dielectric layer 120. In accordance with some embodiments of the present disclosure, the capping layer 121 is formed of a dielectric material, which may include, and is not limited to, aluminum oxide, aluminum nitride, silicon nitride, silicon carbide, silicon oxynitride, silicon carbo-nitride, or the like. A hard mask 122 is formed over the capping layer 121. The hard mask 122 is formed by patterning a hard mask layer to form an opening 128 therein, where the opening 128 defines the pattern of a trench that is to be filled to form a metal line. In accordance with some embodiments of the present disclosure, the hard mask 122 is a metal hard mask formed of titanium nitride, boron nitride, or the like.

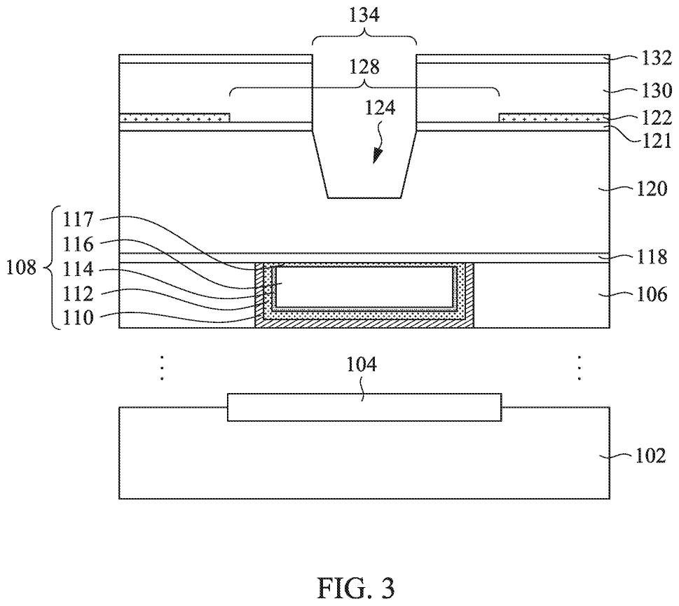

FIGS. 3 through 12 illustrate the process for forming a metal line and a via in accordance with some embodiments. It is appreciated that the examples as shown in FIGS. 3 through 12 recite a dual damascene process. In accordance with alternative embodiments, a single damascene process, in which a metal line, a via, a contact plug, or the like, is formed, which is also contemplated.

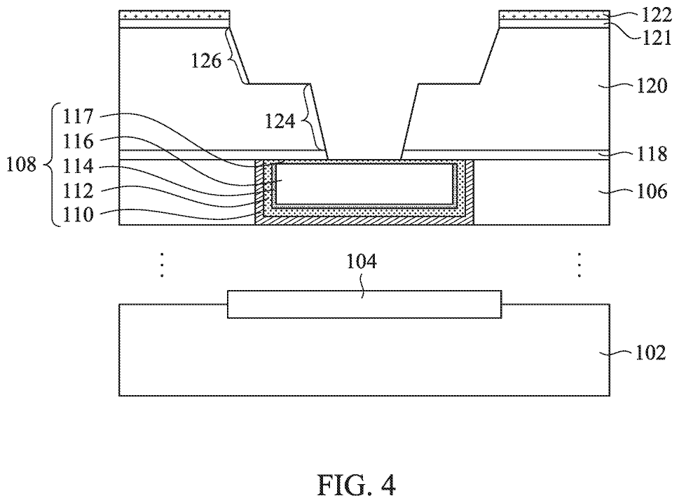

As shown in FIGS. 3 and 4, a via opening 124 and a trench 126 are formed through etching. The respective process is illustrated as process 206 in the process flow 200 shown in FIG. 15. The via opening 124 and the trench 126 may be formed using, for example, photolithography techniques. In an example of the formation process of the via opening 124 and the trench 126, a bottom anti-reflective coating (BARC) layer 130 is formed on the patterned hard mask 122, and a patterned hard mask 132 is formed on the BARC layer 130. In one example, the BARC layer 130 includes organic BARC material formed by a spin-coating technique. The hard mask 132 is formed by patterning a hard mask layer to form an opening 134 therein, where the opening 134 defines the pattern of the via opening 124 that is to be filled to form a via. Through the opening 134, the BARC layer 130 is etched to form the via opening 124. With the via opening 124 extending downward in the etching process, the capping layer 121 and the dielectric layer 120 are then etched.

In accordance with some embodiments of the present disclosure, the etching of the dielectric layer 120 is performed using a process gas comprising fluorine and carbon, wherein fluorine is used for etching, with carbon having the effect of protecting the sidewalls of the resulting opening. With an appropriate fluorine and carbon ratio, the via opening 124 may have a desirable profile. For example, the process gases for the etching include a fluorine and carbon-containing gas(es) such as C₄F₈, CH₂F₂, and/or CF₄, and a carrier gas such as N₂. In an example of the etching process, the flow rate of C₄F₈ is in the range between about 0 sccm and about 50 sccm, the flow rate of CF₄ is in the range between about 0 sccm and about 300 sccm (with at least one of C₄F₈ having a non-zero flow rate), and the flow rate of N₂ is in the range between about 0 sccm and about 200 sccm. In accordance with alternative embodiments, the process gases for the etching include CH₂F₂ and a carrier gas such as N₂. In an example of the etching process, the flow rate of CH₂F₂ is in the range between about 10 sccm and about 200 sccm, and the flow rate of N₂ is in the range between about 50 sccm and about 100 sccm.

During the etching process, the semiconductor device 100 may be kept at a temperature in the range between about 30° C. and about 60° C. In the etching process, plasma may be generated from the etching gases. The Radio Frequency (RF) power of the power source for the etching may be lower than about 700 Watts, and the pressure of the process gases is in the range from about 15 mTorr and about 30 mTorr.

The etching for forming the via opening 124 may be performed using a time-mode. As a result of the etching, the via opening 124 is formed to extend to an intermediate level between the top surface and the bottom surface of the dielectric layer 120. Next, the BARC layer 130 and the patterned hard mask 132 are removed, followed by the further etching of the dielectric layer 120 using the patterned hard mask 122 as an etching mask. In the etching process, which is an anisotropic etching process, the via opening 124 extends down until the etch stop layer 118 is exposed. At the same time the opening 124 is extended downwardly, the trench 126 is formed to extend into the dielectric layer 120. The etch stop layer 118 is subsequently etched with a suitable etchant, and the capping layer 117 is exposed at the bottom of the via opening 124. The resulting structure is illustrated in FIG. 3. In the resulting structure, the via opening 124 is underlying and connected to the trench 126.

In accordance with alternative embodiments, the via opening 124 and the trench 126 are formed in separate photo lithography processes. For example, in a first photo lithography process, the via opening 124 is formed extending down to the etch stop layer 118. In a second lithography process, the trench 126 is formed. The order for forming the via opening 124 and the trench 126 may also be inversed.

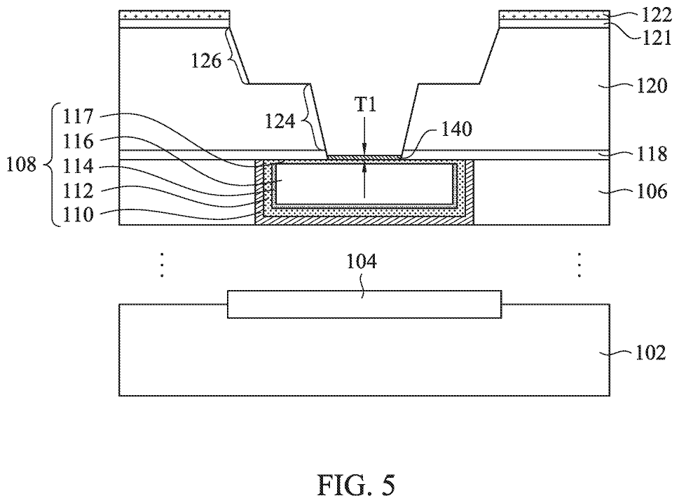

Next, referring to FIG. 5, a wet cleaning process is performed to clean residues from the via opening 124 and the trench 126. The wet cleaning solution may include an inhibitor that is used to protect the exposed portion of the capping layer 117 (such as Co) from being undesirably etched once the capping layer 117 is exposed in the via opening 124, which results in the formation of an inhibitor film 140. The respective process is illustrated as process 208 in the process flow 200 shown in FIG. 15. The inhibitor film 140 is thin, and may have a thickness T1 in the range between about 1 nm and about 2 nm, while the thickness T1 may be greater or smaller. The thickness T1 is related to the type of inhibitor. The inhibitor film 140 may be a mono layer of the inhibitor such as a mono layer of benzotriazole (BTA).

In accordance with some embodiments, the inhibitor includes benzotriazole (BTA). An example of the chemical structure of the BTA includes a benzo ring and three hydrogen atoms attached to the benzo ring, which may be represented by the chemical formula C₆H₅N₃.

In accordance with other embodiments, the inhibitor is selected from other chemicals. These candidate inhibitor materials are hydrophobic, and are preferred to include non-polar groups. The hydrophobic property and the non-polar groups make the candidate inhibitor materials difficult for the adsorption of precursor gases in subsequent deposition processes. The candidate inhibitor materials also have good chelation stability during the wet cleaning, and during the subsequent deposition of the barrier layer. Also, the candidate inhibitor materials are removable during the subsequent plasma de-blocking treatment, as will be discussed. For example, bis-triazolyl indoleamine may be used as inhibitor also. The benzo rings in bis-triazolyl indoleamine also results in the hydrophobic and steric hindrance property.

As a result of adding the inhibitor into the wet cleaning solution, the inhibitor has residue left on the exposed surface of the capping layer 117, resulting in the formation of the inhibitor film 140. For example, when the capping layer 117 comprises Co. Co atoms at the surface of the inhibitor film 140 are bonded to the nitrogen atoms in the BTA. The benzo rings of the BTA face outwardly. Since the benzo rings are unable to be bonded to other atoms (such as Ta atoms and nitrogen atoms in subsequently formed barrier layer), steric hindrance is resulted.

Initially, the inhibitor film 140 may cover a major portion of the exposed surface of the capping layer 117 but not all. To further increase in the coverage, one way is to prolong the time for wet cleaning process. It is realized, however, the prolonging of the wet cleaning time is limited by other factors. For example, prolonging the wet cleaning time too much may cause erosion of the capping layer 117. In accordance with some embodiments of the present disclosure, the wet cleaning time is in the range between about 50 seconds and about 100 seconds.

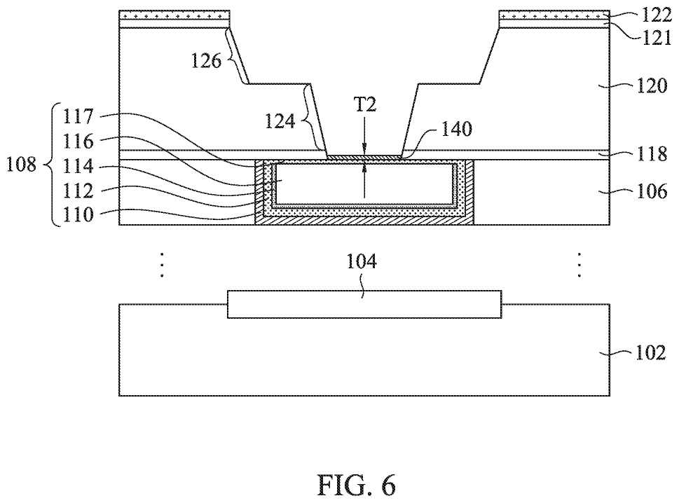

Referring to FIG. 6, in accordance with some embodiments of the present disclosure, to increase the coverage of the inhibitor film 140 without causing the problems as aforementioned, an additional inhibitor film formation process is performed. The respective process is illustrated as process 210 in the process flow 200 shown in FIG. 15. In an example of the processes, the semiconductor device 100 is taken out of the wet cleaning solution and soaked in an inhibitor-forming solution. Since this process is used for further growing the inhibitor film 140, but not for etching the capping layer 117, the chemicals that are used for wet cleaning are not included in the inhibitor-forming solution. For example, amine and H₂O₂ may not be included. Some other chemicals such as glycol, dimethyl sulfide, etc., however, may be added in the inhibitor-forming solution. An inhibitor (such as BTA), which may be the same or different from the inhibitor used in the wet cleaning solution, is added into the inhibitor-forming solution. The semiconductor device 100 is then soaked in the inhibitor-forming solution to further grow, and to increase the coverage of, the inhibitor film 140. In accordance with some embodiments of the present disclosure, the soaking time is in the range between about 30 seconds and about 60 seconds. After the soaking, the inhibitor film 140 may achieve 100% coverage with the thickness increasing from T1 to T2 (T2>T1). In some embodiments, T2 is at least 50% larger than T1. When the BTA used in the inhibitor-forming solution is different from the BTA used in the wet cleaning solution, the further grown inhibitor film 140 may have a first layer of a first BTA with a thickness of T1 and a second layer of a second BTA with a thickness of T2-T1. In various embodiments, the thickened inhibitor film 140 is still thinner than either the barrier layer 110, the liner 112, or the etch stop layer 118. As to be discussed below that the inhibitor film 140 reserves a space to form a thin supplementary liner therein, the relatively smaller thickness of the inhibitor film 140 ensures the supplementary liner has a small thickness as well, which makes the resultant structure resemble a bottom barrier layer free via structure.

There may be, or may not be, the inhibitor film 140 grown on the patterned hard mask 122. Also, when the inhibitor film 140 is grown on the patterned hard mask 122, its thickness is smaller than thickness T2, and/or the coverage of the portions of the inhibitor film 140 on the patterned hard mask 122 is smaller than 100%, for example, smaller than about 50%.

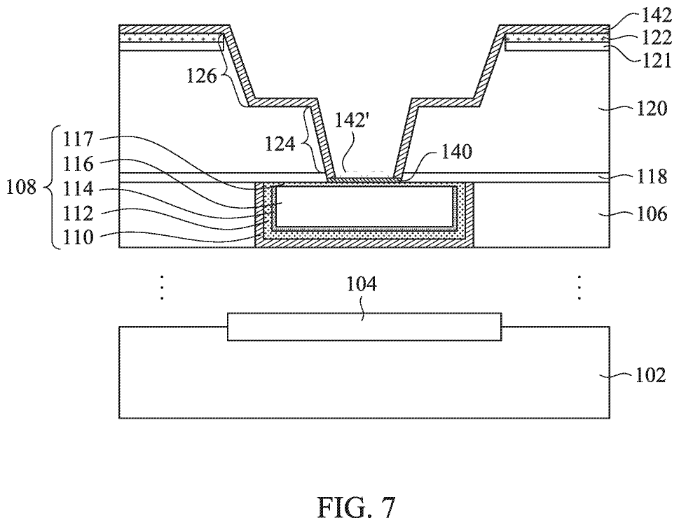

Next, referring to FIG. 7, a conductive barrier layer 142 is deposited lining the via opening 124 and the trench 126, for example, using Atomic Layer Deposition (ALD). The respective process is illustrated as process 212 in the process flow 200 shown in FIG. 15. The barrier layer 142 may be formed of a conductive material such as Ta, TaN, TaC, Ti, TiN, TiC, and other suitable material, and has the function of preventing copper in the subsequently deposited copper-containing material from diffusing into the dielectric layer 120. In accordance with some embodiments of the present disclosure, the barrier layer 50 comprises TaN formed using ALD. The corresponding ALD cycle includes conducting a Ta-containing process gas such as Pentakis Dimethylamino Tantalum (C₁₀H₃₀N₅Ta) into the respective ALD chamber, purging the Ta-containing process gas, conducting a nitrogen-containing process gas such as ammonia into the process chamber, and purging the nitrogen-containing process gas.

The inhibitor film 140 blocks or delays the growth of the barrier layer 142 in the bottom of the via opening 124. This is due to the steric hindrance of the inhibitor film 140, and the steric hindrance is at least partially due to its heterocyclic structure. For example, on the inhibitor film 140, there is a very small possibility of having a TaN molecule (assuming the barrier layer 142 comprises TaN) grown thereon in a ALD cycle, while on the dielectric layer 120, a full layer of TaN is grown in each ALD cycle. Accordingly, after one ALD cycle, a very small percentage of the exposed surface of the inhibitor film 140 has the TaN grown thereon, which acts as the seed for the subsequent growth. Once the TaN is grown, the TaN will grow at the same rate as on the dielectric layer 120. After each cycle, a very small additional area of the inhibitor film 140 is covered by the newly grown TaN. Accordingly, a large percentage of the inhibitor film 140 does not have TaN grown thereon until after multiple ALD cycles. This effect is referred to as growth delay (or incubation delay) on the inhibitor film 140, while there is no grow delay on sidewalls of the dielectric layer 120 since the inhibitor film 140 is not formed on the dielectric layer 120.

Due to the growth delay, and the random seeding of the barrier layer 142 on the inhibitor film 140, after the formation of the barrier layer 142 is finished, there may be substantially no the barrier layer 142 grown on the inhibitor film 140. Alternatively stated, the barrier layer 142 may not extend onto the inhibitor film 140. It is possible that a small amount of the barrier layer 142 is grown on the inhibitor film 140, with the coverage smaller than 100% and higher than 0. In accordance with some embodiments, the barrier layer 142 forms discrete islands 142′ on the surface of the inhibitor film 140, which have random and irregular patterns, and the coverage is less than about 20% of the exposed surface of the inhibitor film 140.

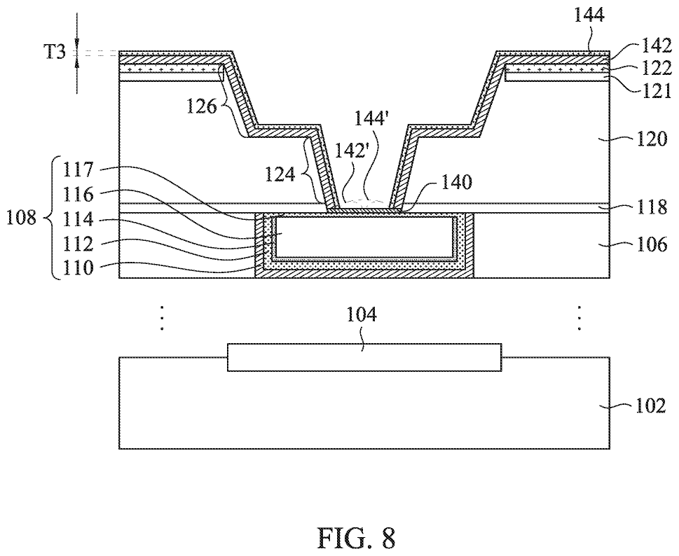

Referring to FIG. 8, a liner 144 is deposited on the barrier layer 142 and lining the via opening 124 and the trench 126, for example, using ALD. The respective process is illustrated as process 214 in the process flow 200 shown in FIG. 15. The liner 144 may be formed of suitable metal, metal nitride, or metal carbide, such as Co, CON and RuN. In furtherance of some embodiments, the liner 144 and the liner 112 have the same material composition. For example, both the liner 144 and the liner 112 may be formed of Co. After the formation of the liner 144, a thickness T3 of the liner 144 may range from about 5 Å to about 10 Å.

The inhibitor film 140 blocks or delays the growth of the liner 144 in the bottom of the via opening 124. This is due to the steric hindrance of the inhibitor film 140, and the steric hindrance is at least partially due to its heterocyclic structure. For example, on the inhibitor film 140, there is a very small possibility of having a Co-containing material (assuming the liner 144 comprises Co) grown thereon in an ALD cycle, while on the barrier layer 142, a full layer of Co-containing material is grown in each ALD cycle. Accordingly, after one ALD cycle, a very small percentage of the exposed surface of the inhibitor film 140 has the Co-containing material grown thereon, which acts as the seed for the subsequent growth. Once the Co-containing material is grown, the Co-containing material will grow at the same rate as on the barrier layer 142. After each cycle, a very small additional area of the inhibitor film 140 is covered by the newly grown Co-containing material. Accordingly, a large percentage of the inhibitor film 140 does not have Co-containing material grown thereon until after multiple ALD cycles. This effect is referred to as growth delay (or incubation delay) on the inhibitor film 140, while there is no grow delay on sidewalls of the barrier layer 142 since the inhibitor film 140 is not formed on the barrier layer 142.

Due to the growth delay, and the random seeding of the liner 144 on the inhibitor film 140, after the formation of the liner 144 is finished, there may be substantially no the liner 144 grown on the inhibitor film 140. Alternatively stated, the liner 144 may not extend onto the inhibitor film 140. It is possible that a small amount of the liner 144 is grown on the inhibitor film 140, with the coverage smaller than 100% and higher than 0. In accordance with some embodiments, the liner 144 forms discrete islands 144′ on the surface of the inhibitor film 140, which have random and irregular patterns, and the coverage is less than about 20% of the exposed surface of the inhibitor film 140. Also as depicted in FIG. 8, some discrete islands 144′ of Co-containing material may overlap on the discrete islands 142′ of TaN from the barrier layer 142.

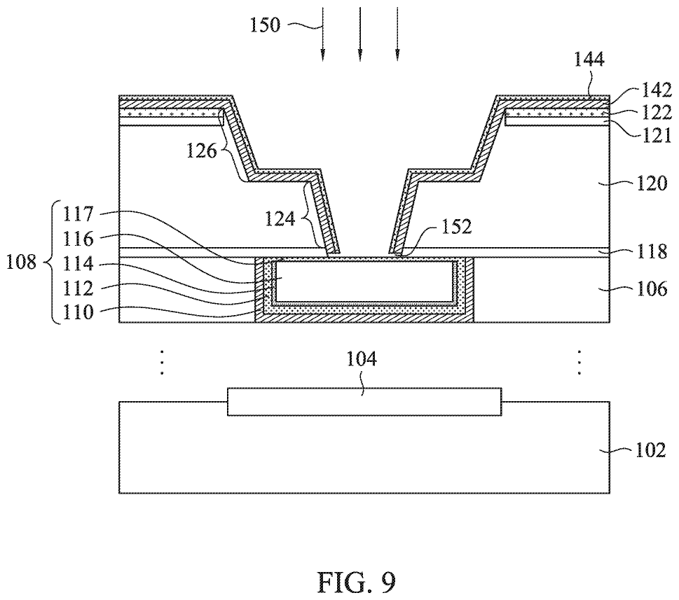

Referring to FIG. 9, a post-deposition treatment 150 is performed to remove the inhibitor film 140. The respective process is illustrated as process 216 in the process flow 200 shown in FIG. 15. The post-deposition treatment 150 may be performed through a plasma treatment. The process gas may include hydrogen (H₂) and a carrier gas such as argon. During the plasma treatment, the temperature of the semiconductor device 100 may be higher than about 200° C., for example, in the range between about 200° C. and about 300° C. The treatment duration may be in the range between about 30 seconds and about 60 seconds. The plasma treatment is also referred to as a plasma de-blocking treatment. As a result of the post-deposition treatment, the inhibitor film 140 is removed, together with the discrete islands 142′ and 144′. In the post-deposition treatment 150, the inhibitor film 140 is decomposed into gases, which are removed. With the inhibitor film 48 being removed, a gap 152 is formed between the capping layer 117 and the end portions of the barrier layer 142 and the liner 144. A bottom portion of the sidewalls of the dielectric layer 120 is exposed by the gap 152. An advantageous feature of performing the post-deposition treatment after the deposition of the barrier layer 142 is that the high-resistive barrier layer 142 would not exist in the bottom of the via opening 124.

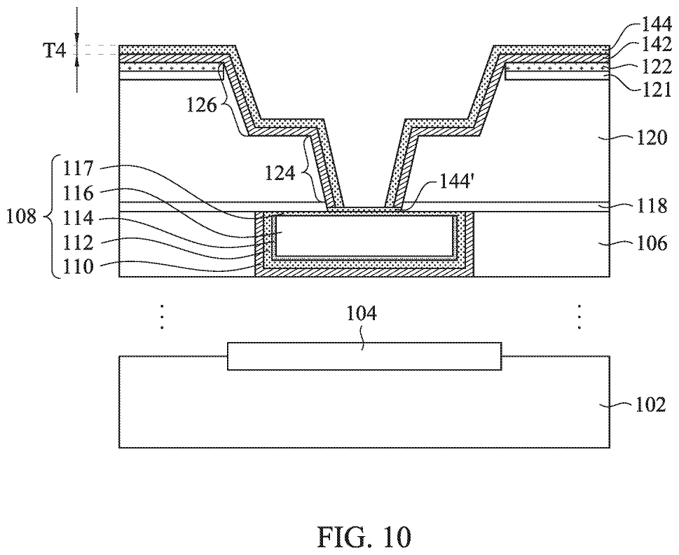

Referring to FIG. 10, a supplementary liner 144′ is conformally deposited on the liner 144 and lining the via opening 124 and the trench 126, for example, using ALD. The respective process is illustrated as process 218 in the process flow 200 shown in FIG. 15. The supplementary liner 144′ also fills the gap 152. The supplementary liner 144′ covers the portion of the top surface of the capping layer 117 that is exposed in the via opening 124 and covers the portion of the sidewalls of the dielectric layer 120 exposed in the gap 152. The supplementary liner 144′ may be formed of suitable metal, metal nitride, or metal carbide, such as Co, CoN and RuN. In furtherance of some embodiments, the supplementary liner 144′ and the liner 144 have the same material composition. For example, both the supplementary liner 144′ and the liner 144 may be formed of Co. A thickness of the supplementary liner 144′ may be smaller than the thickness T3 of the liner 144. In the embodiments that the supplementary liner 144′ and the liner 144 are formed of the same conductive material, the supplementary liner 144′ merges with the liner 144, and equivalently the liner 144 is thickened to a thickness T4 that is larger than the initial thickness T3. In some embodiments, the thickness T4 is about 30% to 80% larger than the initial thickness T3. The thickened liner 144 helps reducing contact resistance. Still further, in the embodiments that the supplementary liner 144′, the liner 144, and the capping layer 117 are made of the same material composition, such as Co, the same material composition merges into a thicker conductive layer between the top surface of the conductive feature 108 and the bottom of the via opening 124, which helps further reducing contact resistance. By filling the gap 152, the liner 144 also separates the barrier layer 142 from contacting the capping layer 117.

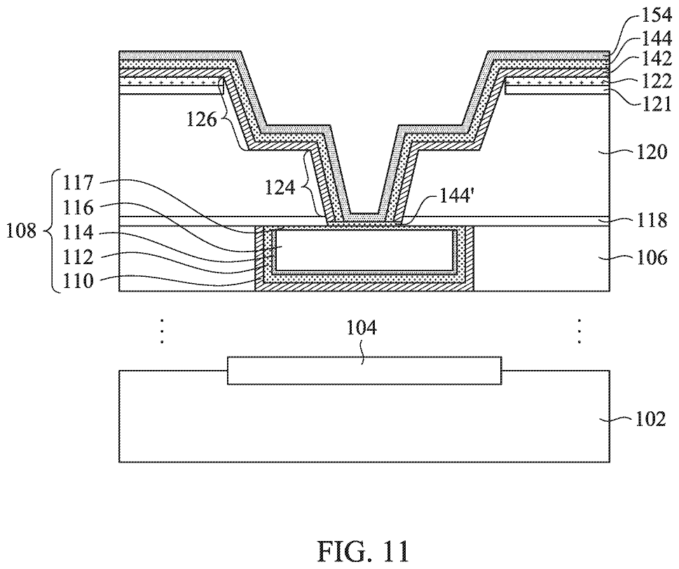

Referring to FIG. 11, a seed layer 154 is formed on the liner 144. The respective process is illustrated as process 220 in the process flow 200 shown in FIG. 15. In some implementations, the seed layer 154 is a metal alloy layer containing at least a main metal element, e.g., copper (Cu), and an additive metal element, e.g., manganese (Mn). In one example, the seed layer 154 is a copper-manganese (CuMn) layer. In other embodiments, Ti, Al, Nb, Cr, V. Y. Tc, Re, or the like can be utilized as an alternative additive metal for forming the seed layer 154. The additive metal element helps improving device electron migration performance. The concentration (atomic percentage) of the additive metal element in the copper-alloy layer may range from about 0.5% to about 5%, in some embodiments. The concentration of the additive metal element in contact structures at a lower metal-layer level may be smaller that of contact structures at a higher metal-layer level. In one example, the copper-alloy for the seed layer 154 and the seed layer 114 is CuMn, and a concentration of manganese in the lower seed layer 114 is smaller than a concentration of manganese in the upper seed layer 154, for example, 1% smaller. This is because, although a higher concentration of additive metal element further helps improving the electron migration performance, a contact resistance is also increased due to the relatively-low resistance of the additive metal element. For conductive features formed in a lower metal-layer level, the generally smaller metal line width and metal line pitch already increase the metal resistance at the lower metal-layer level, and thus a smaller concentration of additive metal element mitigates further increasing the metal resistance. For conductive features formed in a higher metal-layer level, the generally larger metal line width and metal line pitch accommodate a larger concentration of additive metal element without much concern of deteriorating the metal resistance. The seed layer 154 may be deposited by using ALD, CVD, ELD, PVD, or other suitable deposition techniques.

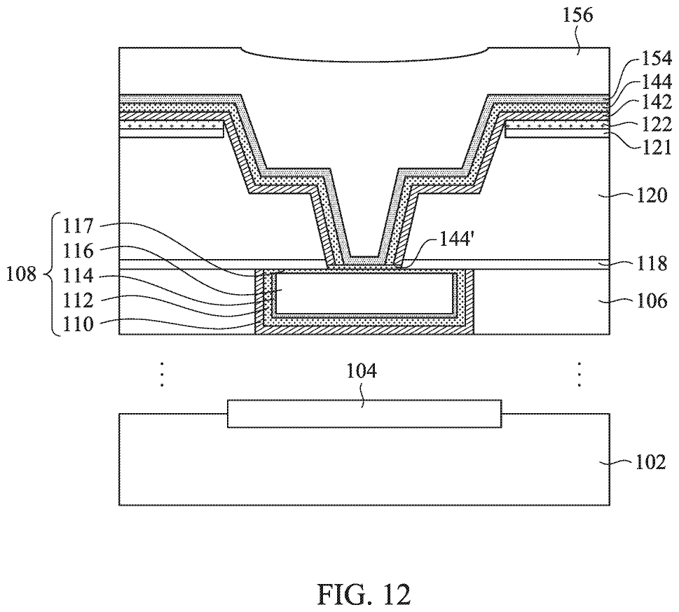

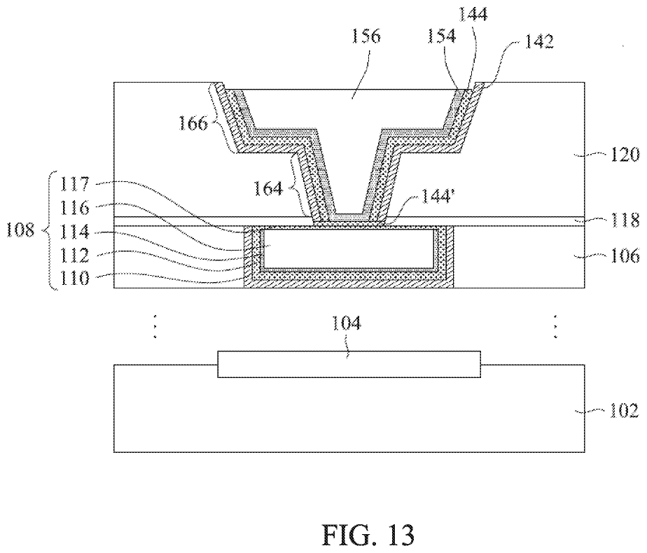

Referring to FIG. 12, a conductive material 156 is deposited to fill the via opening 124 and trench 126. The respective process is illustrated as process 222 in the process flow 200 shown in FIG. 18. The processes as shown in FIGS. 11 and 12 may be in-situ performed in a same vacuum environment, with not vacuum break in between. A part or all of the deposition process in FIGS. 7 through 10 may also be performed in-situ in the same vacuum environment as the processes shown in FIGS. 11 and 12, with no vacuum break in between. In accordance with some embodiments, the deposition of the seed layer 154 includes performing a blanket deposition using Physical Vapor Deposition (PVD), and filling the rest of the via opening 124 and the trench 126 using. for example, electro-plating. A planarization process such as a Chemical Mechanical Planarization (CMP) process or a mechanical polish process may be performed to remove excess portions of conductive material 156, hence forming a via 164 and a metal line 166, as shown in FIG. 13.

Due to the selective formation of the barrier layer 142, the barrier layer 142 includes the portions contacting the dielectric layer 120 to perform the diffusion-blocking function, and does not have portions to separate a bottom portion of the liner 144 (the supplementary liner 144′) in the bottom of the via 164 from the capping layer 117. Since the resistivity of barrier layer 142 is significantly higher (such as two orders to four orders higher) than the resistivity of the conductive material 156, not forming the barrier layer 142 at the interface with the underneath contact structures may significantly reduce the contact resistance of the via 164.

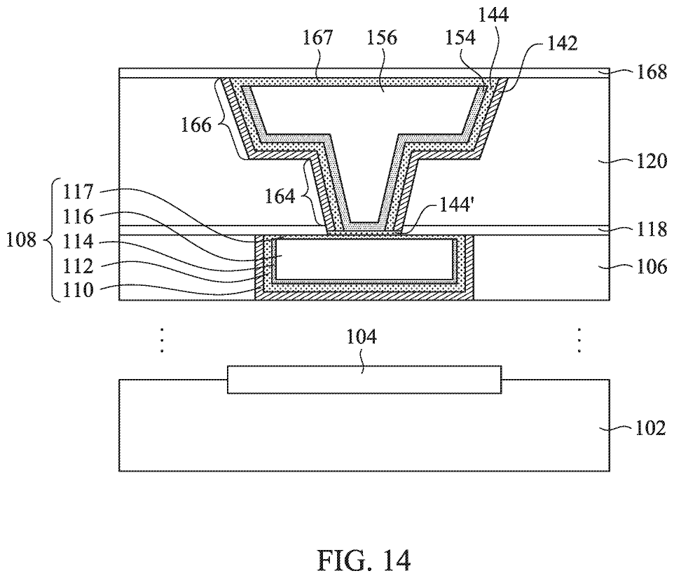

FIG. 14 also illustrates the formation of the capping layer 167 and the etch stop layer 168. The capping layer 167 is deposited on the conductive material 156. The respective process is illustrated as process 224 in the process flow 200 as shown in FIG. 15. In some embodiments, the CMP process performed prior in removing excess portions of the conductive material 156 also slightly recesses the top surfaces of the conductive material 156 and the seed layer 154. The capping layer 167 is deposited on the recessed top surfaces of the conductive material 156 and the seed layer 154. The liner 144 may surround the capping layer 167 and separate the capping layer 167 from contacting the barrier layer 142. In furtherance of some embodiments, the top surfaces of the barrier layer 142, the liner 144, and the capping layer 167 may be substantially coplanar. In some other embodiments, the CMP process also recesses the liner 144, such that the capping layer 167 covers the top surfaces of the liner 144, the seed layer 154, and the conductive material 156. Thus, the capping layer 167 may physically contacts the barrier layer 142.

In accordance with some embodiments of the present disclosure, the capping layer 167 is formed of a conductive material, which may include, and is not limited to, metal, metal nitride, or metal carbide. In some implementations, the capping layer 167 may be formed of Co, CON, RuN, or a combination thereof. In furtherance of some embodiments, the capping layer 167 and the liner 144 have the same material composition. For example, both the capping layer 167 and the liner 144 may be formed of Co. The etch stop layer 168 covers and contacts the dielectric layer 120 and the metal line 166. The etch stop layer 168 is formed of a material that has a high etching selectivity with relative to a subsequently-formed overlying dielectric layer (not shown).

Referring back to FIG. 1, as discussed above, a metal line (and a respective via directly under the metal line) at a higher metal-layer level may have a higher concentration of additive metal element (e.g., manganese) in accordance with some embodiments of the present disclosure. For example, a concentration of manganese at Mtop level may be about 3% to about 5% higher than that at M1 level, and is gradient for metal-layer levels therebetween. In some other embodiments, a metal line at a metal-layer level with a larger metal line pitch may have a higher concentration of additive metal element (e.g., manganese) in accordance with some embodiments of the present disclosure. For example, if M2 level and M3 level have the same metal line pitch, which is larger than the metal line pitch at M1 level and smaller than the metal line pitch at M4, a concentration of manganese at M2 level and M3 level may substantially be the same, which is larger than that at M1 level and smaller than that at M4 level.

The embodiments of the present disclosure have some advantageous features. By forming the conductive barrier layer after the formation of the inhibitor film, since the growth of the inhibitor film on different materials is selective, the resulting conductive barrier layer is selectively formed on the sidewalls of the low-k dielectric layer to perform the diffusion-blocking function, and is not formed on the underlying conductive region to avoid causing an increase in the via contact resistance.

In one exemplary aspect, the present disclosure is directed to a method of manufacturing a semiconductor device. The method includes forming a conductive capping layer over a conductive feature, forming a dielectric layer over the conductive capping layer, forming an opening in the dielectric layer to expose a top surface of the conductive capping layer, forming an inhibitor film at the top surface of the conductive capping layer, depositing a barrier layer on sidewalls of the opening, removing the inhibitor film to expose the top surface of the conductive capping layer, depositing a supplementary liner on the barrier layer and the top surface of the conductive capping layer, and depositing a conductive material on the supplementary liner and filling the opening. In some embodiments, the inhibitor film includes benzotriazole (BTA). In some embodiments, during the depositing of the barrier layer, the inhibitor film delays a growth of the barrier layer on the inhibitor film. In some embodiments, during the depositing of the barrier layer, the barrier layer forms isolated islands on the inhibitor film. In some embodiments, the conductive capping layer includes Co. In some embodiments, the conductive capping layer and the supplementary liner include a same material composition. In some embodiments, the method also includes after the depositing of the barrier layer and prior to the removing of the inhibitor film, depositing a liner on the barrier layer, the liner being stacked between the barrier layer and the supplementary liner. In some embodiments, the supplementary liner and the liner include a same material composition. In some embodiments, during the depositing of the liner, the inhibitor film delays a growth of the liner on the inhibitor film. In some embodiments, the method also includes after the depositing of the supplementary liner and prior to the depositing of the conductive material, depositing a first seed layer. The first seed layer includes an additive metal element with a first concentration, the conductive feature includes a second seed layer that includes the additive metal element with a second concentration, and the first concentration is larger than the second concentration. In some embodiments, the forming of the inhibitor film includes forming an initial inhibitor layer in a first solution, the initial inhibitor layer partially covering the top surface of the conductive capping layer, and enlarging and thickening the initial inhibitor layer to form the inhibitor film in a second solution that is different from the first solution, the inhibitor film fully covering the top surface of the conductive capping layer.

In another exemplary aspect, the present disclosure is directed to a method of forming a semiconductor structure. The method includes forming a first dielectric layer, forming a first opening in the first dielectric layer, depositing a first seed layer in the first opening, the first seed layer including a main metal element and an additive metal element, depositing a first conductive material to fill the first opening, forming a second dielectric layer over the first dielectric layer, forming a second opening in the second dielectric layer, depositing a second seed layer in the second opening, the second seed layer including the main metal element and the additive metal element, and depositing a second conductive material to fill the second opening. The additive metal element has a first concentration in the first seed layer and a second concentration in the second seed layer, and the second concentration is larger than the first concentration. In some embodiments, the main metal element is copper, and the additive metal element is manganese. In some embodiments, each of the first and second concentrations ranges from about 0.5% to about 5%. In some embodiments, the method also includes after the depositing of the first conductive material and prior to the forming of the second dielectric layer, depositing a conductive capping layer on the first conductive material. After the depositing of the second conductive material, the conductive capping layer is vertically between the first conductive material and the second seed layer. In some embodiments, the method also includes after the forming of the second opening, depositing an inhibitor film at a bottom of the second opening, depositing a barrier layer on sidewalls of the second opening but not on the inhibitor film, and prior to the depositing of the second conductive material, removing the inhibitor film from the second opening. In some embodiments, the removing of the inhibitor film exposes a sidewall of the second dielectric layer in the second opening.

In yet another exemplary aspect, the present disclosure is directed to an interconnect structure. The interconnect structure includes a first conductive feature in a first dielectric layer, a conductive capping layer over the first conductive feature, a second dielectric layer over the etch stop layer, and a second conductive feature extending through the second conductive feature. The second conductive feature includes a barrier layer on sidewalls of the second dielectric layer, a liner on the barrier layer and in physical contact with the conductive capping layer, a seed layer on the liner, and a conductive filling layer on the seed layer. In some embodiments, the liner separates the barrier layer from contacting the conductive capping layer. In some embodiments, the seed layer is a first seed layer including a first concentration of an additive metal element, the first conductive feature includes a second seed layer including a second concentration of the additive metal element, and the first concentration is higher than the second concentration.

The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming a semiconductor structure, comprising:
forming a conductive capping layer over a conductive feature;
forming a dielectric layer over the conductive capping layer;
forming an opening in the dielectric layer to expose a top surface of the conductive capping layer;
forming an inhibitor film at the top surface of the conductive capping layer;
depositing a barrier layer on sidewalls of the opening;
removing the inhibitor film to expose the top surface of the conductive capping layer;
depositing a supplementary liner on the barrier layer and the top surface of the conductive capping layer; and
depositing a conductive material on the supplementary liner and filling the opening.

2. The method of claim 1, wherein the inhibitor film includes benzotriazole (BTA).

3. The method of claim 1, wherein during the depositing of the barrier layer, the inhibitor film delays a growth of the barrier layer on the inhibitor film.

4. The method of claim 3, wherein during the depositing of the barrier layer, the barrier layer forms isolated islands on the inhibitor film.

5. The method of claim 1, wherein the conductive capping layer includes Co.

6. The method of claim 5, wherein the conductive capping layer and the supplementary liner include a same material composition.

7. The method of claim 1, further comprising:
after the depositing of the barrier layer and prior to the removing of the inhibitor film, depositing a liner on the barrier layer, wherein the liner is stacked between the barrier layer and the supplementary liner.

8. The method of claim 7, wherein the supplementary liner and the liner include a same material composition.

9. The method of claim 7, wherein during the depositing of the liner, the inhibitor film delays a growth of the liner on the inhibitor film.

10. The method of claim 1, further comprising:
after the depositing of the supplementary liner and prior to the depositing of the conductive material, depositing a first seed layer,
wherein the first seed layer includes an additive metal element with a first concentration, the conductive feature includes a second seed layer that includes the additive metal element with a second concentration, and the first concentration is larger than the second concentration.

11. The method of claim 1, wherein the forming of the inhibitor film includes:
forming an initial inhibitor layer in a first solution, wherein the initial inhibitor layer partially covers the top surface of the conductive capping layer; and
enlarging and thickening the initial inhibitor layer to form the inhibitor film in a second solution that is different from the first solution, wherein the inhibitor film fully covers the top surface of the conductive capping layer.

12. A method of forming a semiconductor structure, comprising:
forming a first dielectric layer;
forming a first opening in the first dielectric layer;
depositing a first seed layer in the first opening, wherein the first seed layer includes a main metal element and an additive metal element;
depositing a first conductive material to fill the first opening;
forming a second dielectric layer over the first dielectric layer;
forming a second opening in the second dielectric layer;
depositing a second seed layer in the second opening, wherein the second seed layer includes the main metal element and the additive metal element; and
depositing a second conductive material to fill the second opening,
wherein the additive metal element has a first concentration in the first seed layer and a second concentration in the second seed layer, and the second concentration is larger than the first concentration.

13. The method of claim 12, wherein the main metal element is copper, and the additive metal element is manganese.

14. The method of claim 12, wherein each of the first and second concentrations ranges from about 0.5% to about 5%.

15. The method of claim 12, further comprising:
after the depositing of the first conductive material and prior to the forming of the second dielectric layer, depositing a conductive capping layer on the first conductive material,
wherein after the depositing of the second conductive material, the conductive capping layer is vertically between the first conductive material and the second seed layer.

16. The method of claim 12, further comprising:
after the forming of the second opening, depositing an inhibitor film at a bottom of the second opening;
depositing a barrier layer on sidewalls of the second opening but not on the inhibitor film; and
prior to the depositing of the second conductive material, removing the inhibitor film from the second opening.

17. The method of claim 16, wherein the removing of the inhibitor film exposes a sidewall of the second dielectric layer in the second opening.

18. An interconnect structure, comprising:
a first conductive feature in a first dielectric layer;
a conductive capping layer over the first conductive feature;
a second dielectric layer over the etch stop layer; and
a second conductive feature extending through the second conductive feature,
wherein the second conductive feature includes:
a barrier layer on sidewalls of the second dielectric layer,
a liner on the barrier layer and in physical contact with the conductive capping layer,
a seed layer on the liner, and
a conductive filling layer on the seed layer.

19. The interconnect structure of claim 18, wherein the liner separates the barrier layer from contacting the conductive capping layer.

20. The interconnect structure of claim 18, wherein the seed layer is a first seed layer including a first concentration of an additive metal element, the first conductive feature includes a second seed layer including a second concentration of the additive metal element, and the first concentration is higher than the second concentration.
